(19) United States
(12) Patent Application Publication
(10) Pub. No.: US 2009/0085155 A1
(43) Pub. Date: Apr. 2, 2009

(54) METHOD AND APPARATUS FOR PACKAGE-TO-BOARD IMPEDANCE MATCHING FOR HIGH SPEED INTEGRATED CIRCUITS

(76) Inventors: Mark J. Bailey, Lake City, MN (US); Todd A. Cannon, Mantorville, MN (US); Haitian Hu, Beacon, NY (US); Nanju Na, Essex Junction, VT (US); Katsuyuki Yonehara, Sagamihara (JP); Deborah E. Zwitter, Williston, VT (US)

Correspondence Address: IBM CORPORATION, 3605 HIGHWAY 52 NORTH, DEPT 917, ROCHESTER, MN, 55901-7829, US

(21) Appl. No.: 11/864,247

(22) Filed: Sep. 28, 2007

(51) Int. Cl. H01L 29/00; G06F 17/50

(52) U.S. Cl. 257/531; 716/7; 257/E29.001

(57) ABSTRACT

A method of package-to-board impedance matching for high speed integrated circuits (ICs). Multiple solder balls are attached to an IC package. The IC package includes multiple conductive interconnect layers, where one of the conductive interconnect layers is coupled to one or more of the multiple solder balls. Multiple vias are coupled between different conductive interconnect layers. An inductive element is coupled between an interconnect lead and a via land in the conductive interconnect layer within the IC package. The physical layout dimensions of the inductive element are configured such that the inductive element provides an inductance value that is sufficient to offset a parasitic capacitance provided by the conductive interconnect layers and the solder balls. The inductive element may be a bond wire, an inductive interconnect, or a spiral interconnect.

### BACKGROUND OF THE INVENTION

1. Technical Field

The present invention relates in general to packaged integrated circuits (ICs) and in particular to impedance matching in packaged ICs. Still more particularly, the present invention relates to an improved method and system for package-to-board impedance matching for high speed ICs.

2. Description of the Related Art

The ball grid array (BGA) packages for integrated circuits (ICs) include multiple solder balls located on an exterior surface. BGA solder balls enable a packaged IC (or IC modules) to be coupled to a printed circuit board (PCB). BGA solder balls, which have large physical dimensions, can also contribute to capacitive loading due to parasitic capacitances between the solder balls and the surrounding power and/or ground plane conductors in an IC package. Capacitive loading can degrade high speed performance by creating undesired reflections and signal attenuation. As transmission rates continue to increase, the performance degradation due to parasitic capacitances caused by BGA solder balls becomes more severe.

Conventional methods of reducing capacitive loading due to BGA solder balls often maximize the distance between the signal path and one or more copper planes in an IC. Increasing this distance by reducing solder ball dimensions can impair mechanical reliability. Adding distance by placing dense voids between copper plane layers to reduce capacitive loading for signal integrity purposes generates a direct tradeoff between the power delivery capability of the IC and the electrical decoupling of the power and ground planes (i.e., the reduction of parasitic capacitance). Heavy voiding in conductor layers above BGAs can also reduce the wire density of the IC package by eliminating the reference plane area that is required to provide impedance controlled (i.e., impedance matched) transmission lines.

### SUMMARY OF AN EMBODIMENT

Disclosed are a method and apparatus for package-to-board impedance matching for high speed integrated circuits (ICs). Multiple solder balls are attached to an IC package. The IC package includes multiple conductive interconnect layers, where one of the conductive interconnect layers is coupled to one or more of the multiple solder balls. Multiple vias are coupled between different conductive interconnect layers. An inductive element is coupled between an interconnect lead and a via land in the conductive interconnect layer within the IC package. The physical layout dimensions of the inductive element are configured such that the inductive element provides an inductance value that is sufficient to offset a parasitic capacitance provided by the conductive interconnect layers and the solder balls. The inductive element may be a bond wire, an inductive interconnect, or a spiral interconnect.

The above as well as additional objectives, features, and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 depicts an exemplary integrated circuit (IC) and an exemplary printed circuit board (PCB), according to a first embodiment of the present invention;

FIG. 2 illustrates an exemplary IC and an exemplary PCB, according to a second embodiment of the present invention;

FIG. 3 illustrates an exemplary IC and an exemplary PCB, according to a third embodiment of the present invention; and

FIG. 4 is a high level logical flowchart of an exemplary method of providing package-to-board impedance matching for high speed ICs, according to an embodiment of the invention.

### DETAILED DESCRIPTION OF AN ILLUSTRATIVE EMBODIMENT

The present invention provides a method and apparatus for package-to-board impedance matching for high speed integrated circuits (ICs).

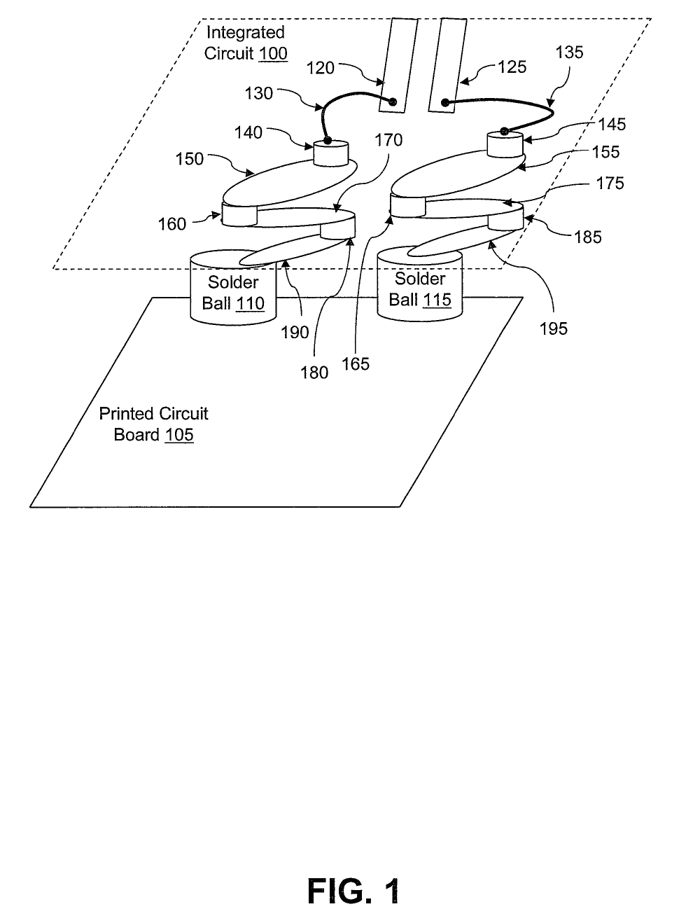

With reference now to FIG. 1, there is depicted an exemplary IC 100 and an exemplary printed circuit board (PCB) 105, according to a first embodiment of the present invention. IC 100 may be a wire-bond type package. As shown, IC 100 includes multiple solder balls, of which first solder ball 110 and second solder ball 115 are illustrated. In one embodiment, multiple solder balls may be configured as a ball grid array (BGA). Solder balls 110 and 115 couple IC 100 to PCB 105. IC 100 also includes multiple interconnect leads, such as first interconnect lead 120 and second interconnect lead 125. Interconnect leads 120 and 125 may be coupled to various logic and/or memory circuits within IC 100. Solder balls 110 and 115 are connected to interconnect leads 120 and 125, respectively, by multiple metal layers and vias. As utilized herein, a metal layer refers to a conductive interconnect layer (e.g., a power plane or a ground plane) within a packaged IC. A via refers to a conductive interconnect that provides a connection between different metal layers within a packaged IC.

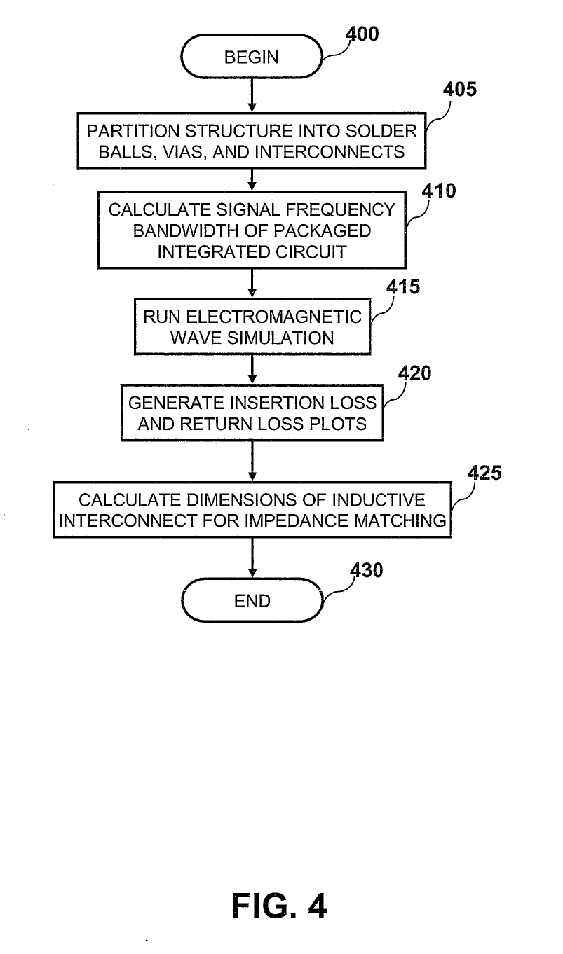

In a first embodiment, first interconnect lead 120 is coupled to an inductive element, such as first bond wire 130. Similarly, second interconnect lead 125 is coupled to second bond wire 135. Bond wires 130 and 135 are composed of a conductive material having a high inductance value. The physical layout dimensions (e.g., length, width, and/or diameter) of bond wires 130 and 135 may also be defined via an impedance matching process, such that the inductance values of bond wires 130 and 135 offset the parasitic capacitances between power planes, ground planes, and/or solder balls within IC 100. The impedance matching process is illustrated in FIG. 4, which is described below.

According to the illustrative embodiment, bond wires 130 and 135 are coupled to first vias 140 and 145, respectively. First vias 140 and 145 are coupled to first metal layers 150 and 155, which are in turn coupled to second vias 160 and 165, respectively. Similarly, second vias 160 and 165 are coupled to second metal layers 170 and 175, which are in turn coupled to third vias 180 and 185, respectively. Third vias 180 and 185 are coupled to third metal layers 190 and 195, respectively, which are in turn coupled to solder balls 110 and 115, respectively.

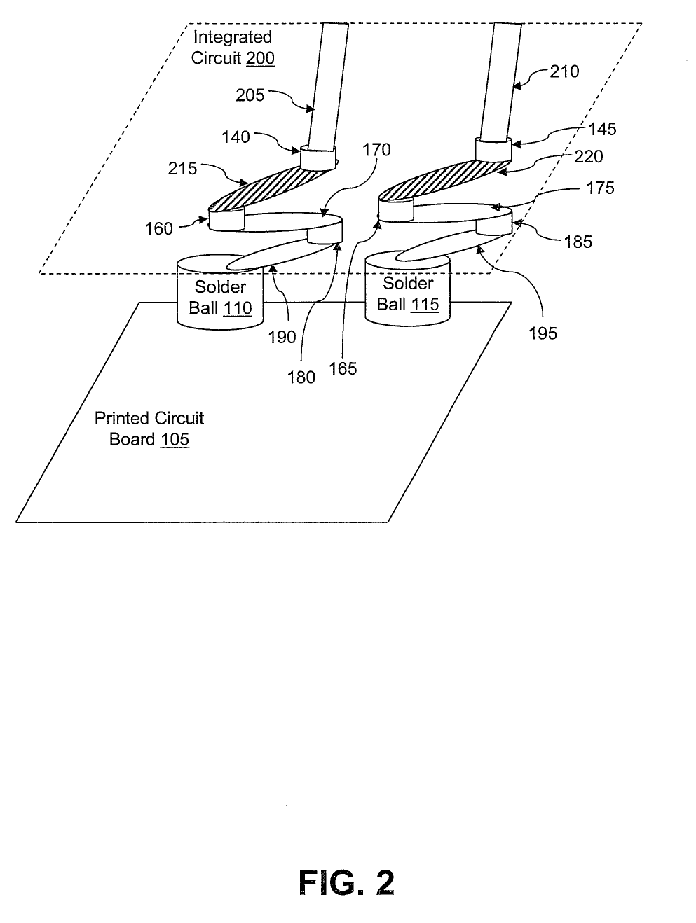

Within the descriptions of the figures, similar elements are provided similar names and reference numerals as those of the previous figure(s). Where a later figure utilizes the element in a different context or with different functionality, the element is provided a different leading numeral representative of the figure number (e.g., 1xx for FIG. 1 and 2xx for FIG. 2). The specific numerals assigned to the elements are provided solely to aid in the description and not meant to imply any limitations (structural or functional) on the invention.

With reference now to FIG. 2, there is depicted an exemplary IC 200 and PCB 105, according to a second embodiment of the present invention. IC 200 may be a wire-bond type package or a flip-chip type package. As shown, IC 200 includes one or more lengthened interconnect leads, such as lengthened interconnect leads 205 and 210. Lengthened interconnect leads 205 and 210 are coupled directly to first vias 140 and 145, respectively, thereby eliminating the need for bond wires (e.g., in a flip-chip type package).

In a second embodiment, IC 200 includes one or more inductive elements, such as inductive interconnects 215 and 220. As shown, inductive interconnects 215 and 220 are coupled between first vias 140 and 145, respectively, and second vias 160 and 165, respectively. Inductive interconnects 215 and 220 thus replace first metal layers 150 and 155 (FIG. 1). In another embodiment, inductive elements may replace one or more other metal layers and/or vias within IC 200. The physical layout dimensions (e.g., length, width, and/or thickness) of inductive interconnects 215 and 220 may be defined via an impedance matching process, such that the inductance values of inductive interconnects 215 and 220 offset the parasitic capacitances between power planes, ground planes, and/or solder balls within IC 200. The impedance matching process is illustrated in FIG. 4, which is described below.

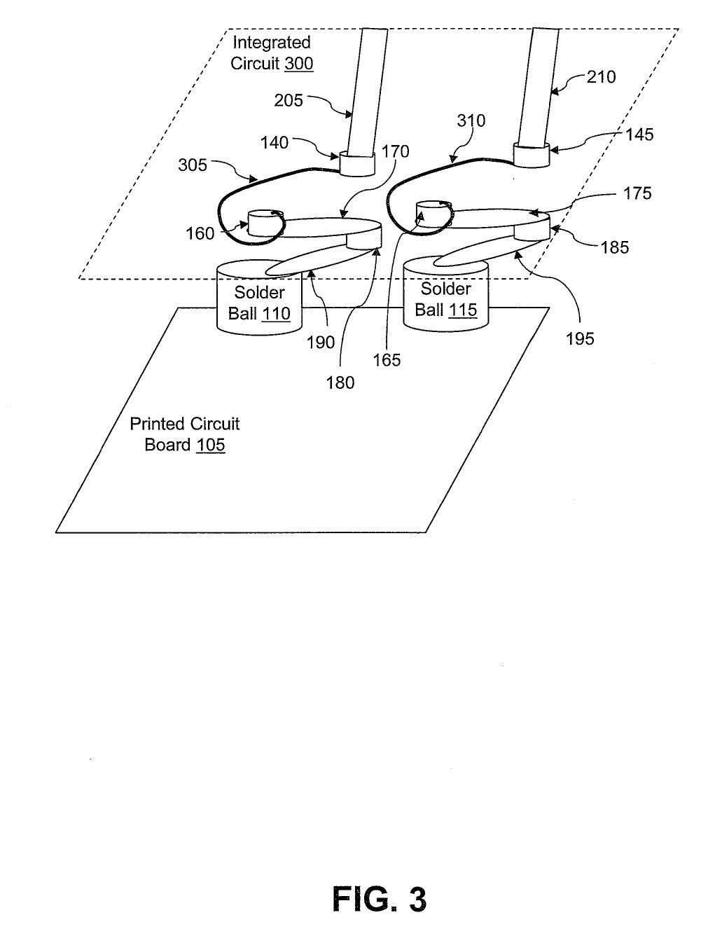

With reference now to FIG. 3, there is depicted an exemplary IC 300 and PCB 105, according to a third embodiment of the present invention. IC 300 may be a wire-bond type package or a flip-chip type package. As shown, IC 300 includes one or more spiral interconnect leads, such as spiral interconnects 305 and 310. As utilized herein, a spiral interconnect lead refers to an inductive metal layer that is configured in a curved shape, such as a spiral, and provides an inductive connection between two vias. As shown, IC 300 includes one or more lengthened interconnect leads, such as lengthened interconnect leads 205 and 210. Lengthened interconnect leads 205 and 210 are coupled directly to first vias 140 and 145, respectively, thereby eliminating the need for bond wires (e.g., in a flip-chip type package).

In a third embodiment, spiral interconnects 305 and 310 are coupled between first vias 140 and 145, respectively, and second vias 160 and 165, respectively. Spiral interconnects 305 and 310 thus replace first metal layers 150 and 155 (FIG. 1). In another embodiment, inductive spiral interconnect elements may replace one or more other metal layers in the signal path of IC 300 in close proximity to the BGA impedance discontinuity (i.e., the source of a parasitic capacitance). The physical layout dimensions (e.g., length, width, thickness, and/or curvature) of spiral interconnects 305 and 310 may be defined via an impedance matching process, such that the inductance values of spiral interconnects 305 and 310 offset the parasitic capacitances between power planes, ground planes, and/or solder balls within IC 300 without additional distances (e.g., voids) between the power planes, ground planes, and/or solder balls. Spiral interconnects 305 and 310 thus provide impedance matching with limited plane voiding. The impedance matching process is illustrated in FIG. 4, which is described below.

Turning now to FIG. 4, there is illustrated a high level logical flowchart of an exemplary method of providing package-to-board impedance matching for high speed packaged ICs. The process begins at block 400 and proceeds to block 405, at which an electromagnetic (EM) simulation program partitions the structure of a pre-defined packaged IC design into multiple element types (e.g., solder balls, vias, and interconnects). The EM simulation program calculates a signal frequency bandwidth of the packaged IC, as shown in block 410. The EM simulation program subsequently runs an EM wave simulation using the pre-defined IC design, as depicted in block 415. The EM simulation program subsequently generates one or more insertion loss plots and return loss plots, as shown in block 420. As utilized herein, insertion loss plots and return loss plots refer to plots of the electrical impedance exhibited by one or more elements in a packaged IC in response to an input signal.

In one embodiment, the EM simulation program may utilize a lumped element impedance matching technique to minimize potential signal loss and delay when calculating the physical layout dimensions of an inductive element. The behavior of interconnects is generally dictated by the transmission line effects of a distributed network at high frequencies. For electrically short distances (e.g., approximately =signal wavelength/100), distributed network behavior of interconnects can be characterized by lumped circuit elements, such as resistances, capacitances, and inductances. A modified inductive discontinuity may thus offset a capacitive discontinuity if an inductive element is configured with physical layout dimensions that provide an inductance within a target range. For example, if a first lumped impedance is represented by a value of Z₁=√(L₁/C₁), and impedance Z₁ is coupled to a much larger impedance Z₀ (i.e. Z₁<<Z₀), then a capacitive discontinuity exists between the two elements. The capacitive discontinuity may be offset by introducing an inductive element L₂ between Z₁ and Z₀, such that Z₁ and L₂ form an impedance Z₂ that is approximately equal to Z₀ (i.e., Z₂={(L₁+L₂)/C₁}≈Z₀).

Returning now to FIG. 4, the EM simulation program calculates the physical layout dimensions of one or more inductive elements (e.g., bond wires, inductive interconnects, or spiral interconnects), such that the inductive elements provide an inductance value that is sufficient to offset the parasitic capacitances between power planes, ground planes, and/or solder balls within the pre-defined packaged IC design (i.e., an L₂ value that provides impedance matching), as depicted in block 425. The EM simulation subsequently outputs the physical layout dimensions to a user, and the process terminates at block 430.

The present invention thus provides package-to-board impedance matching for high speed integrated circuits (ICs). Multiple solder balls, such as solder balls 110 and 115 (FIG. 1), are attached to an IC package. The IC package includes multiple conductive interconnect layers, where one of the conductive interconnect layers is coupled to a solder ball. Multiple vias are coupled between different conductive interconnect layers. An inductive element is coupled between an interconnect lead and a via land in the conductive interconnect layer within the IC package. The physical layout dimensions of the inductive element are configured such that the inductive element provides an inductance value that is sufficient to offset a parasitic capacitance provided by the conductive interconnect layers and the solder balls. The inductive element may be a bond wire (e.g., bond wire 130 of FIG. 1), an inductive interconnect (e.g., inductive interconnect 215 of FIG. 2), or a spiral interconnect (e.g., spiral interconnect 305 of FIG. 3). The present invention provides package-to-board impedance matching with limited plane voiding (i.e., without adding distance between the power planes, ground planes, and/or solder balls) by modifying the physical layout dimensions of IC interconnect components, while adhering to standard manufacturing processes. The present invention thus expands the usable bandwidth of conventional packaged IC technology in a cost effective manner.

It is understood that the use herein of specific names are for example only and not meant to imply any limitations on the invention. The invention may thus be implemented with different nomenclature/terminology and associated functionality utilized to describe the above devices/utility, etc., without limitation.

In the flow chart (FIG. 4) above, while the process steps are described and illustrated in a particular sequence, use of a specific sequence of steps is not meant to imply any limitations on the invention. Changes may be made with regards to the sequence of steps without departing from the spirit or scope of the present invention. Use of a particular sequence is therefore, not to be taken in a limiting sense, and the scope of the present invention is defined only by the appended claims.

While the invention has been particularly shown and described with reference to a preferred embodiment, it will be understood by those skilled in the art that various changes in form and detail may be made therein without departing from the spirit and scope of the invention.

What is claimed is:

1. An integrated circuit (IC) comprising:
a plurality of solder balls;
a plurality of conductive interconnect layers, wherein one of said plurality of conductive interconnect layers is coupled to one of said plurality of solder balls;
a plurality of conductive vias coupled between said plurality of conductive interconnect layers;
one or more interconnect leads; and
an inductive element coupled to said one or more interconnect leads, wherein said inductive element provides an inductance value that is sufficient to offset a parasitic capacitance provided by said plurality of conductive interconnect layers and said plurality of solder balls.

2. The IC of claim 1, wherein said inductive element is a bond wire, wherein a physical layout dimension of said bond wire is configured to provide said inductance value sufficient to offset said parasitic capacitance.

3. The IC of claim 1, wherein said inductive element replaces one of said plurality of conductive interconnect layers, wherein a physical layout dimension of said inductive element is configured to provide said inductance value sufficient to offset said parasitic capacitance.

4. The IC of claim 1, wherein said inductive element is a spiral inductor, wherein a physical layout dimension of said spiral inductor is configured to provide said inductance value sufficient to offset said parasitic capacitance.

5. A method comprising:
partitioning a pre-defined integrated circuit (IC) design into a plurality of element types;
calculating a signal frequency bandwidth of said pre-defined IC design;
executing an electromagnetic (EM) wave simulation; and
calculating a physical layout dimension of an inductive element in said pre-defined IC design, wherein said inductive element provides an inductance value sufficient to offset a parasitic capacitance provided by a plurality of conductive interconnect layers and a plurality of solder balls in said pre-defined IC design.

6. The method of claim 5, wherein said plurality of element types include solder balls, interconnect elements, and via elements.

7. The method of claim 5, wherein executing said EM wave simulation further comprises generating an insertion loss plot and a return loss plot.
